(19) United States
(12) Patent Application Publication
(10) Pub. No.: US 2023/0176475 A1
(43) Pub. Date: Jun. 8, 2023

(54) CONFORMAL MICRO- OR NANOPATTERNED NANOIMPRINT LITHOGRAPHY MASTER AND METHODS OF MAKING AND USING THE SAME

(71) Applicant: Smart Material Solutions, Inc., Raleigh, NC (US)

(72) Inventors: Stephen Furst, Raleigh, NC (US); Nichole Cates, Raleigh, NC (US); Lauren Micklow, Raleigh, NC (US)

(73) Assignee: Smart Material Solutions, Inc., Raleigh, NC (US)

(21) Appl. No.: 17/917,474

(22) PCT Filed: Apr. 7, 2021
(86) PCT No.: PCT/US2021/026186

§ 371 Date: Oct. 6, 2022

Related U.S. Application Data
(60) Provisional application No. 63/006,370, filed on Apr. 7, 2020.

(51) Int. Cl. G03F 7/00; G03F 1/38; B29C 59/02; B29C 35/02

(52) U.S. Cl. CPC G03F 7/0002; G03F 1/38; B29C 59/022; B29C 59/026; B29C 35/0261; B29C 2059/023

(57) ABSTRACT

A conformal micro- or nanopatterned nanoimprint lithography (NIL) master and methods of making and using same is disclosed. A conformal foil or film master with a patterned surface is provided for imprinting a substantially uniform pattern on a non-flat substrate. The conformal foil or film master may be mounted to a soft backing, which may be mounted to a rigid backing, to form conformal master structure. When pressed against a non-flat substrate, the conformal foil or film master substantially conforms to the contours and/or topology of the non-flat substrate to provide a substantially uniform pattern thereon.

### RELATED APPLICATION DATA

This application claims priority pursuant to Article 8 of the Patent Cooperation Treaty to U.S. Provisional Patent Application No. 63/006,370 filed Apr. 7, 2020, the entirety of which is incorporated by reference herein.

### FIELD

The technology described herein generally relates to nanoimprint lithography (NIL), and more particularly to flexible micro- or nanopatterned master molds and methods of making and using the same.

### BACKGROUND

In nanoimprint lithography (NIL), nanopatterns and/or micropatterns are used for patterning surfaces. Nanopatterns and micropatterns refer to regular arrays of features tiled together. These patterns may be used to create or impart desirable macroscale effects to materials, such as anti-reflectivity, diffractive color, and ultrahydrophobicity (or superhydrophobicity). Some common patterning processes include electron-beam lithography, interference lithography, and focused ion beam milling. However, these techniques can have drawbacks. For example, conventional methods and techniques can be expensive and slow. Additionally, these methods and techniques traditionally create rigid master molds that must be replicated into a softer material in order to imprint surfaces that are not nearly perfectly flat. Further, when pressing a rigid flat master into a non-flat substrate, only the high spots of the substrate will be patterned. Accordingly, the technology described herein overcome issues and drawbacks in conventional methods of nanoimprint lithography by providing flexible conformal master molds and semi-transparent molds and using such master molds to pattern other materials and substrates, for instance non-flat substrates.

### SUMMARY

This summary is provided to introduce a selection of concepts in a simplified form that are further described below in the detailed description. This summary is not intended to identify key features or essential features of the claimed subject matter, nor is it intended to be used in isolation as an aid in determining the scope of the claimed subject matter.

Embodiments of the technology described herein are directed towards flexible and/or conformal master molds and semi-transparent molds, and the patterning thereof.

According to some embodiments, flexible and/or conformal foil or film masters, for example a thin foil or thin film, can be fabricated having a micro- and/or nanopatterned surface that is configured to impart or otherwise transfer the micro- and/or nanopattern to a surface of a nonpatterned substrate. In some instances, the micro- and/or nanopatterned surface of a flexible foil or film master mold is created through an indenting process, for instance a mechanical indenting process. The flexible and/or conformal foil or film masters can additionally be incorporated into a conformal master structure, where the master structure can include a soft backing and/or rigid backing. In some embodiments, the flexible and/or conformal foil or film masters, or the master structures, can be formed as a sheet structure or a cylindrical structure, e.g. a sleeve, which in some instances can be a seamless sleeve. Additionally, the flexible and/or conformal foil or film masters can be self-supporting.

According to some further embodiments, semi-transparent photomasks can be fabricated having micro- and/or nanopatterned features configured to impart or otherwise transfer the micro- and/or nanopattern to the surface of a nonpatterned substrate. A semi-transparent photomask can include a transparent substrate and an opaque material disposed or deposited on the transparent substrate. The opaque material can be patterned with micro-and/or nanopatterned features such that the thickness of the opaque material varies across the transparent substrate. In some instances, semi-transparent photomasks are created through an indenting process. In some embodiments a semi-transparent photomask can be formed as a sheet structure or a cylindrical structure, e.g. a sleeve, which in some instances can be a seamless sleeve. Additionally, the semi-transparent photomasks can be self-supporting.

According to some even further embodiments, semi-transparent photomasks can be fabricated having micro- and/or nanopatterned features configured to impart or otherwise transfer the micro- and/or nanopattern to the surface of a nonpatterned substrate. A transparent substrate can be provided and patterned with micro- and/or nanopattern features. An opaque material can then be deposited on the patterned transparent substrate to fill the micro- and/or nanopattern features thereon.

Additional objects, advantages, and novel features of the invention will be set forth in part in the description which follows, and in part will become apparent to those skilled in the art upon examination of the following, or can be learned by practice of the invention.

### BRIEF DESCRIPTION OF DRAWINGS

Aspects of the technology presented herein are described in detail below with reference to the accompanying drawing figures, which are not necessarily drawn to scale, wherein:

FIGS. 1A-C illustrate an example flexible master, in accordance with some aspects of the technology described herein;

FIGS. 2A-C illustrate an example flexible master structure, in accordance with some aspects of the technology described herein;

FIGS. 3A-C depict an example method for fabricating a flexible mold, in accordance with some aspects of the technology described herein;

FIGS. 4A-C depict an example method for fabricating a semi-transparent mold, in accordance with some aspects of the technology described herein;

FIGS. 5A-B depict an example method for fabricating a semi-transparent mold, in accordance with some aspects of the technology described herein;

FIG. 6 is a schematic of an example method for fabricating a flexible and/or semi-transparent mold, in accordance with some aspects of the technology described herein;

FIG. 7 is a schematic of an example method for fabricating a flexible and/or semi-transparent mold, in accordance with some aspects of the technology described herein; and

FIG. 8 is a schematic of an example method for fabricating a flexible and/or semi-transparent mold, in accordance with some aspects of the technology described herein.

### DETAILED DESCRIPTION

The subject matter of aspects of the present disclosure is described with specificity herein to meet statutory requirements. However, the description itself is not intended to limit the scope of this patent. Rather, the inventors have contemplated that the claimed subject matter might also be embodied in other ways, to include different steps or combinations of steps similar to the ones described in this document, in conjunction with other present or future technologies. Moreover, although the terms “step” and/or “block” can be used herein to connote different elements of methods employed, the terms should not be interpreted as implying any particular order among or between various steps disclosed herein unless and except when the order of individual steps is explicitly described.

Accordingly, embodiments described herein can be understood more readily by reference to the following detailed description, examples, and figures. Elements, apparatus, and methods described herein, however, are not limited to the specific embodiments presented in the detailed description, examples, and figures. It should be recognized that the exemplary embodiments herein are merely illustrative of the principles of the invention. Numerous modifications and adaptations will be readily apparent to those of skill in the art without departing from the spirit and scope of the invention.

In addition, all ranges disclosed herein are to be understood to encompass any and all subranges subsumed therein. For example, a stated range of “1.0 to 10.0” should be considered to include any and all subranges beginning with a minimum value of 1.0 or more and ending with a maximum value of 10.0 or less.

All ranges disclosed herein are also to be considered to include the end points of the range, unless expressly stated otherwise. For example, a range of “between 5 and 10” or “5 to 10” or “5-10” should generally be considered to include the end points 5 and 10.

Further, when the phrase “up to” is used in connection with an amount or quantity; it is to be understood that the amount is at least a detectable amount or quantity. For example, a material present in an amount “up to” a specified amount can be present from a detectable amount and up to and including the specified amount.

Additionally, in any disclosed embodiment, the terms “substantially,” “approximately,” and “about” may be substituted with “within [a percentage] of” what is specified, where the percentage includes 0.1, 1, 5, and 10 percent.

The presently disclosed subject matter now will be described more fully with reference to the accompanying drawings, in which some, but not all embodiments of the presently disclosed subject matter are shown. The presently disclosed subject matter may be embodied in many different forms and should not be construed as limited to the embodiments set forth herein; rather, these embodiments are provided so that this disclosure will satisfy applicable legal requirements. Indeed, many modifications and other embodiments of the presently disclosed subject matter set forth herein will come to mind to one skilled in the art to which the presently disclosed subject matter pertains having the benefit of the teachings presented in the foregoing descriptions and the associated drawings. Therefore, it is to be understood that the presently disclosed subject matter is not to be limited to the specific embodiments disclosed and that modifications and other embodiments are intended to be included within the scope of the present subject matter.

Micro- and nanopatterns can impart desirable properties to various materials, including optical, wetting, and adhesion properties, amongst others, to materials or substrates. Patterning such materials can, for example, be accomplished through nanoimprint lithography (NIL) and photolithography. In particular, roll-to-roll NIL and roll-to-roll photolithography can utilize one or more cylindrical molds and/or other high throughput roll-to-roll techniques to continuously pattern (e.g. micro- or nanopattern) films and/or other substrates for various high-tech applications including, but not limited to display technologies, augmented and virtual reality (i.e. immersive environments) and antimicrobial or self-cleaning surfaces.

Accordingly, NIL is a process by which a master mold having a micro- or nano-scale pattern is placed into contact with an imprintable material or substrate to replicate the mold's pattern into the imprintable material through processes such as thermal embossing and/or ultraviolet (UV) NIL. In thermal embossing, a mold is heated, typically above the glass transition temperature of the imprintable material, and pressed into the imprintable material to soften it so that it can fill the mold's features. The mold is then cooled in order to harden the imprintable material and the mold is subsequently removed from the imprintable material to reveal the imprinted features, such as micro- or nanoscale pattern features. Thermal embossing can also be used to pattern a material as a material is extruded on or through the mold.

Curing processes can also be utilized to replicate a mold's pattern onto a material or substrate using NIL. Such processes start with an uncured material that can fill the mold's features while it is in liquid form. The material is then cured, for example, through the application of heat, light (such as UV light) or chemical agents. By way of the curing process, the material is hardened to preserve the pattern on the material, and the hardened patterned material is subsequently removed from the mold.

Soft lithography may also be utilized, where a polymer, often an elastomeric replica of a master mold, is used as the mold for a second-generation replication of a different material.

In a photolithography process, photocurable materials such as UV-curable polymers and photoresists can also be patterned by illumination through a photomask. A photomask is a semi-transparent master with a pattern formed by opaque and transparent regions. Illumination of a photoresist though a photomask transfers the photomask's pattern into the photoresist by selectively exposing only the illuminated regions of the resist. Subsequent development steps remove the exposed or unexposed regions of positive or negative photoresists, respectively. In many cases, photolithography is used with etching or liftoff processes to transfer a resist's pattern into another material, such as a ceramic or metal. Combining photolithography with NIL enables unique opportunities. Traditional NIL results in three-dimensional (3D) surface textures with a residual (scum) layer. Etching or liftoff processes require the removal of this residual layer with a de-scum process like an oxygen plasma etch. Photolithography, on the other hand, usually results in binary patterns with no residual layer, wherein the patterned material is either full thickness or completely absent. The absence of a residual layer is often advantageous, since descum processes are not needed. However, control over the 3D surface texture is an advantage of NIL patterning. Combining photolithography with NIL by illuminating through a semi-transparent mold combines the advantages of NIL and photolithography to create 3D patterns with no residual layer. Such a process can also cure materials with thicknesses that are larger than the depth of features in the master mold, effectively increasing the feature height and the range of possible patterns.

The lithography techniques described herein generally rely, in part, on a master mold that serves as a starting template. In theory, such a mold can be applied in either roll-to-roll, roll-to-plate, or plate-to-plate (also known as batch) NIL process. A common drawback in NIL is the high cost of this initial master mold. Common mold materials include silicon, PDMS copies of a silicon master, nickel shims, and various metals including copper, nickel, aluminum, stainless steel, or brass. These molds can be patterned through a multi-step process including electron-beam lithography or UV-interference lithography, both of which are used to selectively expose a photoresist (resist) layer. An optional etch step can transfer the resist's pattern into another material. Second- and third-generation replicas can be made through processes, for example, by curing polymers, such as polydimethylsiloxane (PDMS) in contact with a mold to create a soft PDMS stamp or through metallization of a textured mold to create a nickel shim These second- and third-generation replicas can be used in subsequent replication steps as a soft, flexible, or conformal mold.

According to some methods, the fabrication of a flexible and/or conformal master or mold for use in NIL processes is accomplished through an indenting process, such as ultrasonic nanocoining. In this method, a nano- or micro-pattern can be indented into a metal drum that is spinning on a lathe using an actuator to create a seamless, metal master. This indenting process directly writes the pattern and eliminates the need for etching. This indenting process can be used to seamlessly transfer a pattern into, for example, a metal at high speeds, thereby creating a master mold. According to various embodiments of the technology described herein, various indenting processes may be utilized to create a cylinder, sleeve (e.g. a seamless sleeve), foil, and semi-transparent masters for UV NIL, thermal NIL, or photolithography.

Described herein are methods for the fabrication and use of micro- and/or nanopatterned flexible and/or conformal molds which can be used for imparting complex features (e.g. via micro- and/or nanometer scale patterns) to various materials or substrates. It will be appreciated that the term nanoimprint lithography (NIL) as used herein can refer to one or more of thermoplastic nanoimprint lithography, photo nanoimprint lithography, and ultraviolet nanoimprint lithography. In some example embodiments, a flexible and/or conformal NIL master is a micro- or nanopatterned foil or film master for providing a uniform pattern on a substrate, for example a non-flat substrate. In some other example embodiments, a conformal NIL master is a micro- or nanopatterned semi-transparent mold (e.g. integrating transparent and opaque materials) for providing a micro- or nanopatterned photomask for use in a micro- or nanopatterning process.

According to some embodiments, the presently disclosed subject matter provides a flexible and/or conformal micro- or nanopatterned nanoimprint lithography (NIL) master and methods of making and using the same. Additionally, the presently disclosed subject matter can be applied to UV assisted NIL, thermal embossing (thermoplastic), thermoset (starting as an uncured liquid that then cures either thermally or while in contact with the mold), or other types of molding processes.

In some embodiments, flexible and/or conformal foil or film masters can be fabricated having a micro- and/or nanopatterned surface that is configured to impart or otherwise transfer the micro- and/or nanopattern to the surface of a substrate. For example, the flexible and/or conformal micro- or nanopatterned foil or film master can provide a uniform pattern on non-flat substrates. In some instances, the micro- and/or nanopatterned surface of a foil or film master mold is created through an indenting process, for example a conformal foil or film master can be patterned by step-and-repeat indenting and/or ultrasonic nanocoining. It will be appreciated that the masters described herein, such as foil or film masters or semi-transparent photomasks can be flexible, for example having the ability to conform to a non-flat substrate, and can further be conformal, for example having the ability to accurately preserve and transfer or imprint a micro- and/or nanopattern to another material or substrate. The foil or film can be fabricated from a material that can be used in an NIL process including, but not limited to, one or more of aluminum, copper, brass, high-phosphorous nickel, plastic(s), any number of polymers, ceramics or other dielectric material, amongst others. In some instances, a foil and/or film master can be made up of multiple layers of materials to form a multi-layered foil and/or film or combinations thereof. In some instances, a foil or film master having a micro- and/or nanopatterned surface can have a thickness from about 0.001 mm to about 0.5 mm or for example about 0.001 inches to about 0.02 inches.

According to some further embodiments, the foil or film master can be a part of a flexible and/or conformal master structure. For instance, the foil or film can be mounted to a soft backing, for example an airbag, rubber, and/or foam backing. According to some even further embodiments, the conformal master structure can include a rigid backing to support the soft backing, for example the rigid backing can be a rigid plate or block. In some embodiments, a micro- or nanopatterned NIL master provides a conformal master structure that includes a stack of a foil and/or film master, a soft backing, and a rigid backing.

In some embodiments, a seamless sleeve can be fabricated having a micro- and/or nanopatterned surface that is configured to impart or otherwise transfer that micro- and/or nanopattern to the surface of a substrate. In some instances, the micro- and/or nanopatterned surface of a seamless sleeve is created through an indenting process, for example a seamless sleeve can be patterned by step-and-repeat indenting and/or ultrasonic nanocoining. The seamless sleeve can be made of a material that can be used in an NIL process including, but not limited to, one or more of aluminum, copper, brass, high-phosphorous nickel, plastic(s), any number of polymers, ceramics or other dielectric material, amongst others. In some instances, the seamless sleeve is a foil or film, and in some other instances, the seamless sleeve is self-supporting. In some instances, the seamless sleeve having a micro- and/or nanopatterned surface can have a thickness from about 0.001 mm to about 0.5 mm.

In some embodiments, a semi-transparent photomask can be fabricated having a micro- and/or nanopattern, where the pattern is created through an opaque material that is deposited on a transparent material which is configured to impart or otherwise transfer the micro- and/or nanopattern to another material or substrate, such as a photocurable material. In some instances, the micro- and/or nanopatterned opaque material is generated through an indenting process, for example through step-and-repeat indenting and/or ultrasonic nanocoining. In some instances, the transparent material can be glass, quartz, fused silica, plastic, and/or any other suitable material. The transparent material can be provided as a sheet, film, sleeve, tube, or cylinder. In some other instances, the opaque material can be a metal. After the micro- and/or nanopatterned opaque material is generated through an indenting process it will be appreciated that the thickness of the opaque material will vary across the length and/or width of the opaque material deposited on the transparent substrate, thereby providing a grayscale photomask having a three-dimensional surface texture, which can be subsequently used to cure, for example, a photocurable polymer, accordingly transferring a micro- and/or nanopattern to the polymer or other material.

In some embodiments, a micro- and/or nanopatterned semi-transparent photomask can be fabricated by filling a patterned transparent material with an opaque material. In some instances, the transparent material may be patterned via an indenting process and/or an imprinting process.

In some other embodiments, a method for fabricating a flexible and/or conformal foil or film and/or semi-transparent master is provided. A foil or film can be provided on a base cylinder as a seamless sleeve or layer of material. Alternatively, in some instances, a conformal foil or film can be provided as a ribbon over a tensioning chuck. The foil or film can then be patterned, for example through an indenting process with a micro- and/or nanopattern and subsequently cut into segments. The segments can further be flattened. In some instances, the foil or film can be diamond turned to an optical finish prior to patterning. In some instances, the patterning (e.g. indenting) can be achieved through repeated indenting with a die. The die can be patterned with a micro- and/or nanopattern with a focused ion beam or through masking and etching. In some instances, the indenting of the flexible and/or conformal foil or film and/or semi-transparent master is achieved through the use of a diamond die and/or a piezo-driven actuator.

In some embodiments, the flexible and/or conformal micro- or nanopatterned master and methods of making and using the same include: fabricating and using flexible foils and/or films as nanoimprint lithography masters, fabricating patterned sleeves (e.g. seamless sleeves) and foils or films and cutting them into flats, indenting pattern features on the foils and/or films up to at least 5 μm, using a non-elliptical tool paths, and using a step-and-repeat process and/or ultrasonic nanocoining to pattern the foils and/or films.

Generally, NIL masters (also referred to as stamps, molds, master molds, moulds, templates, shims, tools, and stampers) include structures that can be used for replication of components or for making working stamps that are then used for production of components. Masters contain micro- and nanostructures (i.e. patterns) that when transferred to a final product, such as another material or substrate, will give a specific functionality with a desired performance, irrespective of whether the final product is of optical, electrical, magnetic, chemical, or another character. In some instances, masters may be formed, for example, from metals, silicon, or fused silica. Patterns can subsequently be transferred to different materials or substrates, for instance nickel, polymers, or hybrid polymers, such as polydimethylsiloxane (PDMS) or ormocers.

Accordingly, the presently disclosed methods enable direct patterning of a flexible and/or conformal master mold by repeatedly indenting features into a foil or film. For some indenting methods, very high patterning rates can be achieved. Even when the patterning rate is lower, this technique offers lower costs than competing technologies such as electron-beam lithography, which require vacuum and subsequent chemical processing.

The presently disclosed methods were derived from a need to make thin, seamless sleeves for use in roll-to-roll imprinting systems. Such sleeves have been used in the past wherein the sleeve is slid over a solid drum that may have internal heating or cooling. The heat passes easily through the thin foil and into the polymer, which softens while in contact with the drum. These heating and cooling drum cores are expensive, making a replaceable sleeve ideal for changing patterns. However, a drawback of these configurations is that many users cannot make use of a seamless sleeve because they use batch imprinting (plate-to-plate) rather than roll-to-roll imprinting. Batch imprinting tools are generally flat and made for silicon masters using traditional wafer-processing techniques, such as lithography. By contrast, a seamless sleeve can be cut and flattened such that it can used in a batch imprinting tool. Accordingly, any thin metal foil or film that is patterned on one side (seamless or otherwise), such as a conformal foil or film master, can be pressed into a flat, a curved or freeform surface, thereby serving as a highly versatile master mold for NIL processes.

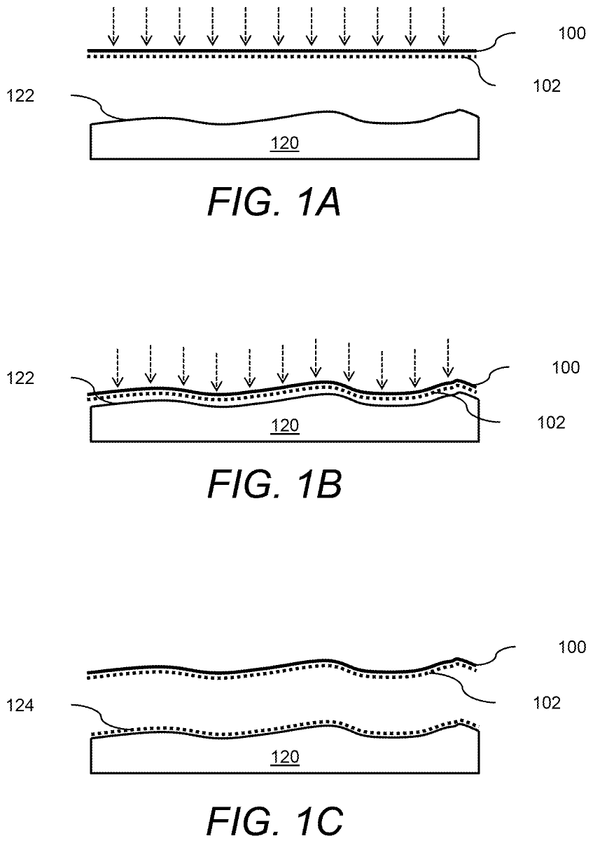

Referring now to the figures, with reference to FIG. 1A, FIG. 1B, and FIG. 1C, side views of an example flexible and/or conformal master or mold 100 is depicted, which is one example of a micro- or nanopatterned NIL master as described herein. flexible and/or conformal master 100 includes a patterned surface 102, the patterned surface 102 including micro- or nanopatterned features, which can be indented or otherwise imprinted onto a surface of the flexible and/or conformal master. In some embodiments, the micro- or nanopatterned features may include one-dimensional and/or two dimensional periodic and/or aperiodic micro- or nano-scale features. flexible and/or conformal foil or film master 100 may be, for example, a metal foil, such as, but not limited to, aluminum, copper, brass, electroformed copper, nickel coated with a high phosphorous nickel, electroformed nickel shim, or a plastic film. Flexible and/or conformal master 100 may also be formed of polymers, ceramics, and/or other materials that can be indented or otherwise imprinted with a micro- or nanopattern. The size of the foils or films may be, for example, a few mm up to meters wide and long, and the thickness may be, for example, from about 0.001 inches to about 0.02 inches or for example from about 0.001 mm to about 0.5 mm.

Flexible and/or conformal master or mold 100 can be a self-supporting foil or film that is ductile enough to receive indents from a die, i.e. has the ability to be patterned by a die with micro- and/or nanofeatures. Additionally, flexible and/or conformal master or mold 100 can be thin and compliant enough to be pressed onto another surface or substrate (e.g., a non-flat substrate 120) in a process to transfer the pattern to the surface or substrate without damaging or otherwise altering the pattern on flexible and/or conformal master or mold 100. FIG. 1A depicts flexible and/or conformal master or mold 100 prior to pressing onto a non-flat substrate 120 that is provided with an unpatterned substrate surface 122 (e.g., a substantially smooth surface). FIG. 1B depicts flexible and/or conformal master or mold 100 with patterned surface 102 being pressed onto and/or into unpatterned substrate surface 122 of non-flat substrate 120. In so doing, flexible and/or conformal master or mold 100 substantially conforms to the contours and/or topology of non-flat substrate 120. In some instances, as master or mold 100 is pressed onto and/or into non-flat substrate 120, a micro- or nanopattern, such as that of patterned surface 102 can be transferred to the unpatterned substrate surface 122 of non-flat substrate 120 via one or more nanolithography processes. FIG. 1C shows flexible and/or conformal master or mold 100 being released from non-flat substrate 120 but still substantially holding the shape of the contours and/or topology of non-flat substrate 120. FIG. 1C depicts that the action of flexible and/or conformal master or mold 100 conforming to and pressing into and/or onto non-flat substrate 120 imprints or otherwise transfers the features of patterned surface 102 of master or mold 100 into the unpatterned substrate surface 122 thereby leaving behind a patterned substrate surface 124 on non-flat substrate 120. Thus, flexible and/or conformal master or mold 100 can be used to provide a pattern, e.g. a substantially uniform pattern, to a surface of non-flat substrate 120. In some instances, once used, master or mold 100 can be used again on a different non-flat substrate that has different contours and/or topology and the flexible and/or conformal master or mold 100 can “reconform” to the different substrate.

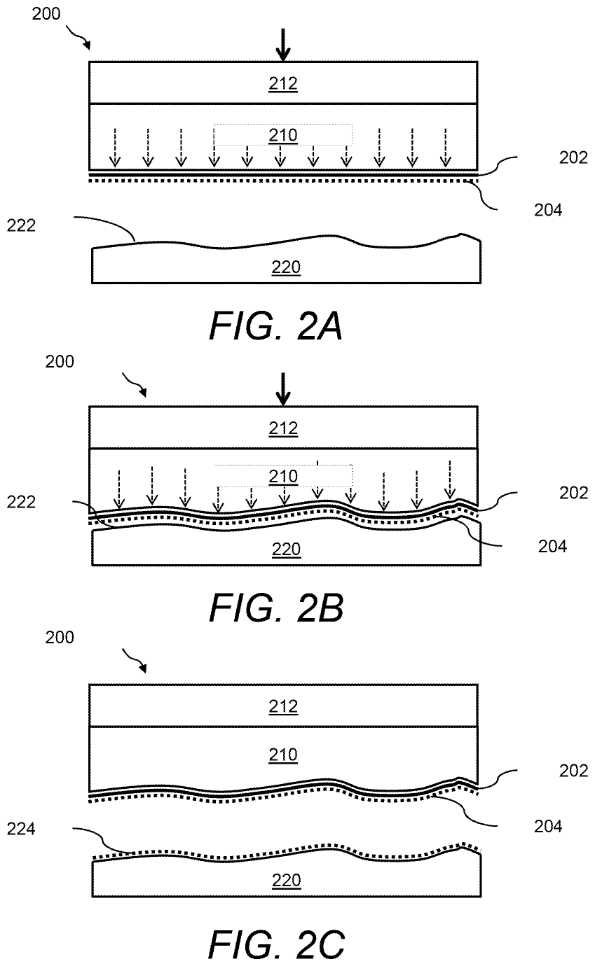

Turning now to FIG. 2A, FIG. 2B, and FIG. 2C, side views of an example of a master structure 200 are depicted that can be used in a micro- or nanopatterning process as described herein, for example flexible and/or conformal master structure 200 can be used to press conformal master 202 onto and/or into a non-flat substrate 220. In this instance master 202 is mounted or otherwise affixed to a soft backing 210, which is then mounted to a rigid backing 212 to form master structure 200. In some example embodiments, rigid backing 212 can be a rigid plate or block of any suitable material configured to support soft backing 210. In some embodiments, soft backing 210 can be made up of an airbag, a soft rubber, and a foam, amongst other materials. It will be appreciated that conformal master structure may include additional layers not depicted, and additionally master 202, soft backing 210, and rigid backing 212 can be respectively attached or affixed by any suitable means. In some instances, master structure 200 can provide a conformal distributed pressure mechanism by which flexible and/or conformal mold 202 can be pressed onto and/or into a non-flat substrate (e.g. non-flat substrate 220) to provide a uniform pattern thereon.

In accordance with FIG. 1A through FIG. 2C, flexible and/or conformal master 100 and/or master structure 200 facilitates the use of thin foils or films that are textured or patterned on one side with a micro- or nanoscale pattern that can be imprinted or otherwise transferred to a softer material. Using a thin foil or film as a master mold thus enables the pattern to be imprinted on, or transferred to, non-flat surfaces as the mold can conform to the substrate, for example as in NIL processes such as soft-lithography, and provide uniform patterning.

In some embodiments, semi-transparent molds can be fabricated and used in accordance with the technology described herein. Semi-transparent molds are made up of patterned opaque films that have variations in the thickness of the opaque film which enable variations in light transmission through the film. The thinner regions of the opaque film will be more transparent and the thicker regions will be more opaque. In some regions, the opaque film can have a thickness at or approaching zero, resulting in maximum light transmission at those regions. In some instances, a semi-transparent mold can serve as a photomask (e.g. a grayscale photomask) for use in photolithography and NIL processes.

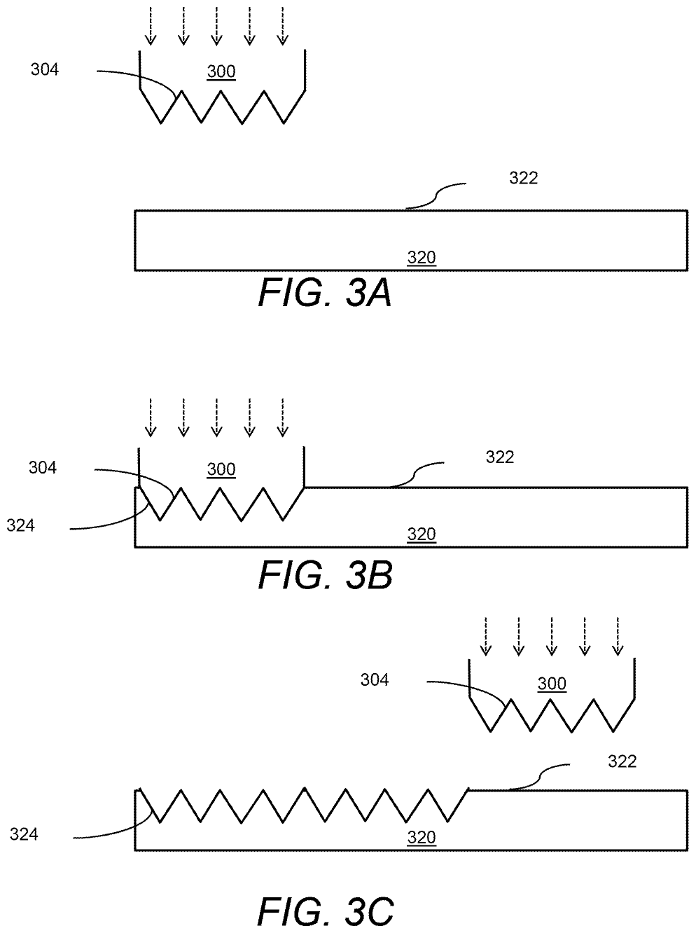

With reference to FIGS. 3-8, example methods for forming master molds (e.g., flexible and/or conformal master 100 of FIG. 1 and/or master structure 200 of FIG. 2), and semi-transparent molds are illustrated. In some instances, by using a hard patterned die, features can be indented or otherwise transferred into a foil or film or other material and/or substrate. The foil or film or other material can be ductile enough to receive indents from a die to generate a pattern thereon. Additionally, the foil or film or other material can also be thin and compliant enough to be pressed conformally onto another surface without damaging or otherwise altering the pattern on the master mold.

FIG. 3A, FIG. 3B, and FIG. 3C depict side views illustrating the fabrication of a mold, for example a conformal master, in accordance with embodiments of the present disclosure. For instance, FIGS. 3A-C depict a die 300 and a mold 320 at various stages of the fabrication process. It will be appreciated that mold 320 may be a conformal master and/or semi-transparent mold. FIG. 3A depicts die 300 with a patterned die surface 304 and a mold 320 with an unpatterned mold surface 322. The patterned die surface 304 is includes micro- and/or nanoscale features thereon, for example one and/or two dimensional periodic and/or aperiodic features. FIG. 3B depicts the patterned die surface 304 of die 300 indenting or otherwise transferring the pattern to mold 320 to generate a patterned mold surface 324. FIG. 3C depicts die 300 and mold 320 after patterning has been created on mold 320 (e.g. through indenting) in different locations across mold 320 which increases the surface area of patterned mold surface 324.

According to some aspects, multiple indents or sets of indents and/or patterning may be stitched together. Pattern stitching can be achieved through several processes including, but not limited to, ultrasonic nanocoining and step-and-repeat indenting. Ultrasonic nanocoining uses a die mounted on an ultrasonic actuator to indent the surface of a continuously rotating cylinder or disk at ultrasonic frequencies. Very high patterning rates can be achieved with this method. Unlike ultrasonic nanocoining, the film or foil does not continuously move during step-and-repeat indenting. Instead, the film or foil is held stationary while a die indents it. After each indent, the film or foil is translated relative to the die and stopped before the die indents the film or foil again. Step-and-repeat indenting has lower patterning rates since fewer indents can be made per second, but it still offers lower costs and superior shape control.

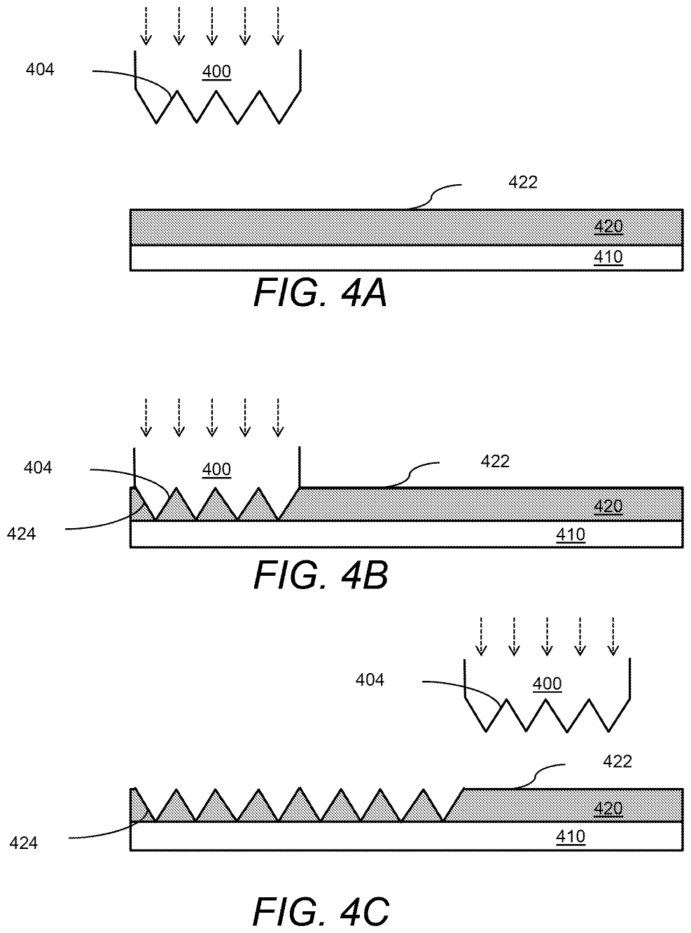

Looking now at FIG. 4A, FIG. 4B, and FIG. 4C, side views illustrating an example fabrication of a semi-transparent mold 400 are depicted, in accordance with embodiments of the present disclosure. FIG. 4A depicts die 402 having a patterned die surface 404 (e.g. a micro- and/or nanopattern) can indent an opaque film 420 that is layered on a transparent substrate 410. It will be appreciated that opaque film 420 may be bonded or otherwise affixed to transparent substrate 410 using any suitable means. Opaque film 420 can be provided having an unpatterned opaque film surface 422. In some embodiments, transparent substrate 410 can be a transparent foil, film, sleeve, or other substrate or combination of the foregoing. FIG. 4B depicts patterned die surface 404 of die 400 indenting or otherwise transferring the pattern to opaque film 420 to generate patterned opaque film 424. FIG. 4C depicts die 300 after patterning (e.g. creating multiple indents or sets of indents) at different locations across opaque film 420. In this way, the patterned surface area of patterned opaque film 424 can be increased. As shown in FIGS. 4B and 4C, patterned opaque film 424 varies in thickness along its length and/or width due to the fabrication process. The variations in thickness of patterned opaque film 424 result in light transmission variations through patterned opaque film 424 as a function of location, thereby creating a photomask (e.g. grayscale NIL photomask). According to embodiments described herein, a fabricated grayscale NIL photomask can be used to combine the advantages of photolithography and NIL by enabling the creation of surface textures without a residual layer. It will be appreciated that semi-transparent mold 400 can be flexible in order to conform to another substrate (e.g. a non-flat substrate) during a lithography process.

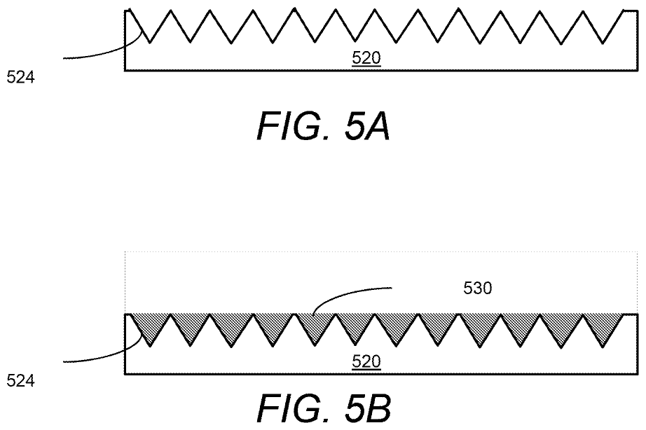

FIG. 5A and FIG. 5B illustrate another example fabrication of a semi-transparent mold, in accordance with embodiments of the present disclosure. FIG. 5A depicts a transparent mold 520 with a patterned transparent mold surface 524 that can be generated using methods described herein or via another suitable imprinting process. FIG. 5B depicts transparent mold 520 having an opaque material 530 deposited in a way to backfill patterned transparent mold surface 524 such that there is variation in the thickness of opaque material 530 across transparent mold 520. The deposition of opaque material 530 can be achieved through a variety of solution and/or vapor deposition processes, for example spin coating, dip coating, doctor blading, evaporation, and sputtering. In some instances, excess opaque material 530 may be removed through additional processing steps such as polishing, squeegeeing, and/or diamond turning.

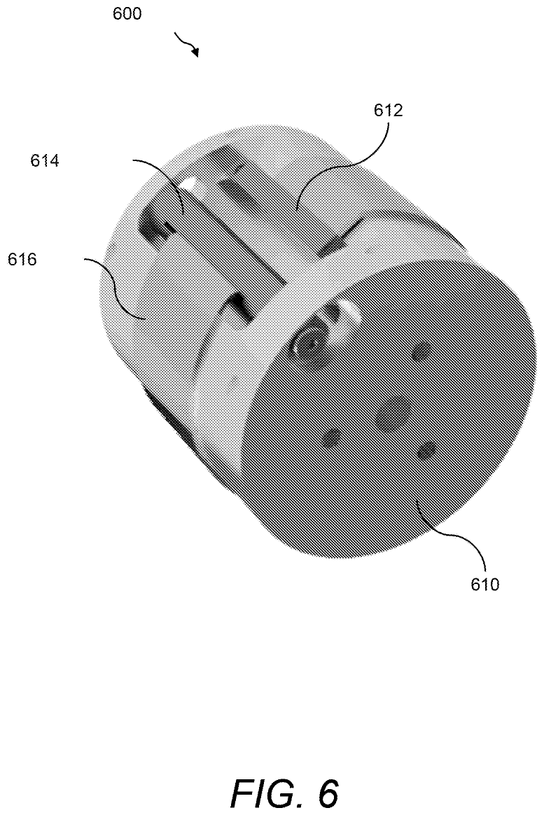

During the fabrication of flexible and/or conformal molds and/or semi-transparent molds, the foils or films being used can be supported, for example during the patterning or indenting processes. FIGS. 6-8 illustrate various example methods of mechanically supporting foils or films during the patterning and/or indenting process to fabricate flexible and/or conformal and/or semi-transparent molds. For example, such support methods can utilize a foil chuck, mandrel, or solid substrate as a support.

Referring now to FIG. 6, FIG. 6 is a perspective view of an example support method used in the fabrication of conformal molds and/or semi-transparent molds, in accordance with embodiments of the present disclosure. A tensioning chuck 600 can be used to secure, for example, a thin foil ribbon 616 on the outside of a cylinder so that it has a solid backing during the patterning or indenting process. Tensioning chuck 600 can include, for example, a cylindrical base 610, a clamp 612, a tensioning spool 614, and a foil ribbon 616 secured thereon. Accordingly, foils and/or films may be provided as a ribbon (e.g. foil ribbon 616) that is mounted on the cylindrical tensioning chuck 600 and placed under tension. As depicted, foil ribbon 616 is wrapped around cylindrical base 610 and clamped on one end via clamp 612. The other end of foil ribbon 616 wraps around tensioning spool 614. Tensioning spool 614 can be rotated to apply tension in foil ribbon 616, enabling it to be diamond-turned or polished then patterned and/or indented using nanocoining or similar processes. Both clamp 612 and tensioning spool 614 can be recessed beneath the surface of the cylindrical base 610 so that the outside of foil ribbon 616 can be turned on a lathe.

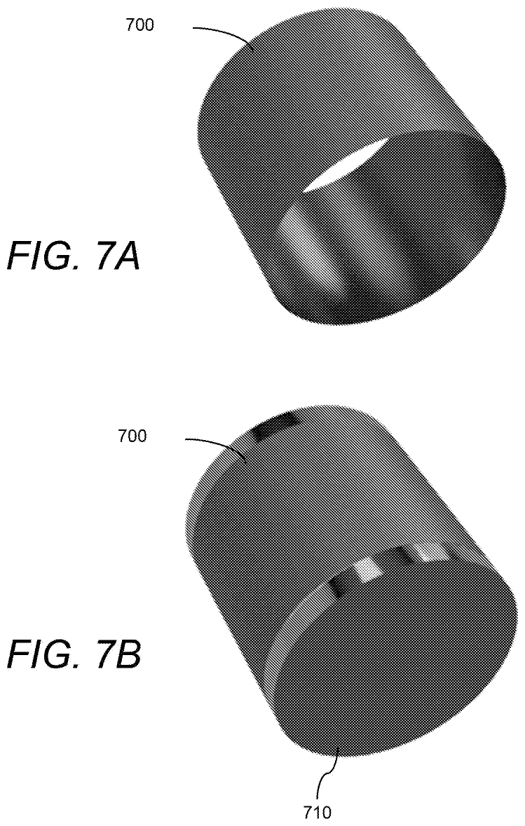

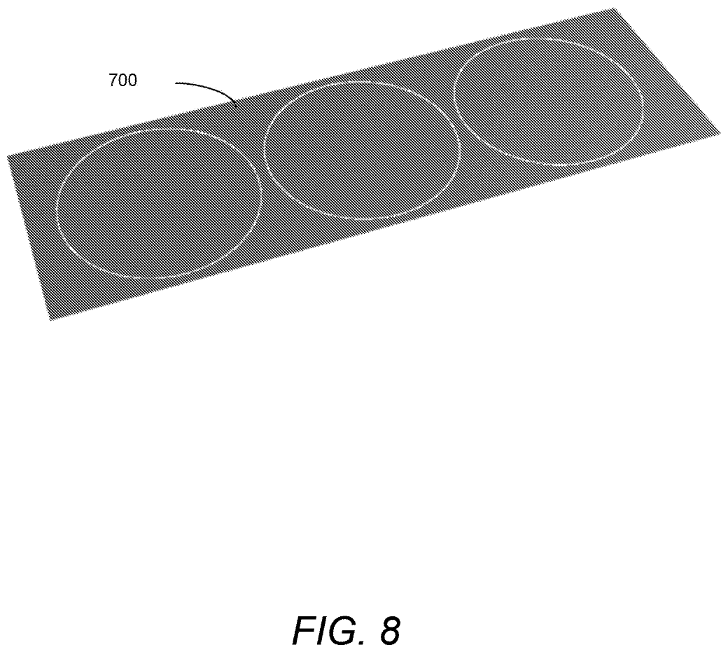

FIGS. 7A-7B depict another example method for fabricating conformal molds and/or semi-transparent molds, in accordance with embodiments of the present disclosure. In some instances, mandrels can be used to mechanically support sleeves (films, foils, or solid substrates in the form of a tube), as shown, for example, in FIG. 7A, FIG. 7B, and FIG. 8. The mandrel 710 may or may not be expandable. FIG. 7A shows a perspective view of an example of a sleeve 700. FIG. 7B shows a perspective view of an example of sleeve 700 on a mandrel 710. It must be possible to load a sleeve 700 onto a mandrel 710 prior to indenting and remove the sleeve 700 after indenting, but the mandrel 710 must provide sufficient mechanical support to prevent movement of the sleeve 700 relative to the mandrel 710 during patterning and/or indenting. In some embodiments, air pressure or thermal expansion differential can enable loading of a sleeve 700 onto a mandrel 710 and removal of a sleeve 700 from a mandrel 710 while ensuring that the sleeve 700 fits snuggly onto the mandrel 710 to ensure stable mechanical support during indenting using, for example, an ultrasonic nanocoining or step-and-repeat indenting.

Alternatively, mandrels can consist of a base cylinder made from a material, such as a polymer, that is coated with a metal or other malleable layer through evaporation, sputtering, CVD or other process. This malleable layer can be patterned through an indenting process then removed from the base cylinder to create a very thin, conformal foil.

An optional adhesive or lubricant may be added between the foil ribbon 616 or sleeve 710 and the foil tensioning chuck 600 or mandrel 710 to ensure facile loading and removal as well as sufficient mechanical stability during indenting. In some embodiments, diamond turning is performed on the foil ribbon or sleeve prior to indenting to create a smooth surface. A foil chuck, mandrel, or solid substrate will also mechanically support the mold materials during the optional diamond turning process.

A sleeve 700 may be transformed into a conformal micro- or nano-patterned conformal mold, such as conformal foil mold 100. For example, FIG. 8 shows sleeve 700 that has been unrolled and cut into multiple pieces that can be pressed into a flattened foil. The indented sleeve (e.g., sleeve 700) of a foil or film (e.g., flexible and/or conformal master 100) can be cut using, for example, laser cutting, a water jet, scissors, or the like. At an optional next step, the cut indented sleeve (e.g., sleeve 700) of a foil or film (e.g., flexible and/or conformal master 100) is flattened by, for example, pressing with foam, pressing with rubber, heating and pressing, or the like.

Methods of fabricating a flexible and/or conformal master and/or semi-transparent photomask are provided. At a first step, a foil or film is provided over a base cylinder, the foil or film formed as a seamless sleeve or sheet and/or ribbon of material. In some instances, a sheet and/or ribbon of material can be provided over a tensioning chuck. In some instances, the foil or film is diamond tuned to an optical finish prior to indenting and/or patterning.

At a next step, the foil or film is indented with a pattern of micro- or nanopatterned features using, for example, a piezo-driven actuator. In some instances, the indenting and/or patterning is accomplished via a die, for example a diamond die. The die can be patterned with the micro- or nanopatterned features by a focused ion beam or a masking and etching process.

At a next step, the indented seamless sleeve (e.g., seamless sleeve 300) of conformal foil (e.g., flexible and/or conformal foil master 100) is removed from the base cylinder or tensioning chuck and cut using, for example, laser cutting, a water jet, scissors, or the like.

At a next step, the cut indented seamless sleeve (e.g., seamless sleeve 300) of conformal foil (e.g., conformal foil master 100) can be flattened by, for example, pressing with foam, pressing with rubber, heating and pressing, or the like.

Throughout this specification and the claims, the terms “comprise,” “comprises,” and “comprising” are used in a non-exclusive sense, except where the context requires otherwise. Likewise, the term “include” and its grammatical variants are intended to be non-limiting, such that recitation of items in a list is not to the exclusion of other like items that can be substituted or added to the listed items.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some embodiments±100%, in some embodiments±50%, in some embodiments±20%, in some embodiments±10%, in some embodiments±5%, in some embodiments±1%, in some embodiments±0.5%, and in some embodiments±0.1% from the specified amount, as such variations are appropriate to perform the disclosed methods or employ the disclosed compositions.

Further, the term “about” when used in connection with one or more numbers or numerical ranges, should be understood to refer to all such numbers, including all numbers in a range and modifies that range by extending the boundaries above and below the numerical values set forth. The recitation of numerical ranges by endpoints includes all numbers, e.g., whole integers, including fractions thereof, subsumed within that range (for example, the recitation of 1 to 5 includes 1, 2, 3, 4, and 5, as well as fractions thereof, e.g., 1.5, 2.25, 3.75, 4.1, and the like) and any range within that range.

Although the foregoing subject matter has been described in some detail by way of illustration and example for purposes of clarity of understanding, it will be understood by those skilled in the art that certain changes and modifications can be practiced within the scope of the appended claims.

Many different arrangements of the various components and/or steps depicted and described, as well as those not shown, are possible without departing from the scope of the claims below. Embodiments of the present technology have been described with the intent to be illustrative rather than restrictive. Alternative embodiments will become apparent from reference to this disclosure. Alternative means of implementing the aforementioned can be completed without departing from the scope of the claims below. Certain features and subcombinations are of utility and can be employed without reference to other features and subcombinations and are contemplated within the scope of the claims.

1. A flexible master comprising:
a foil or film comprising at least one patterned surface, the patterned surface being a pattern of micro- or nanopatterned features configured to impart the pattern to an unpatterned surface, wherein the micro- or nanopatterned features are generated through an indenting process.

2. The flexible master of claim 1, wherein the foil or film is a metal.

3. The flexible master of claim 2, wherein the foil or film is at least one of aluminum, copper, brass, high phosphorous nickel, polymer, or ceramic material.

4. The flexible master of claim 1, wherein the foil or film has a thickness from about 0.001 mm to about 0.5 mm.

5. The flexible master of claim 1, further comprising a soft backing.

6. The flexible master of claim 5, wherein the soft backing is at least one of an airbag, a rubber and a foam.

7. The flexible master of claim 1, further comprising a rigid backing.

8. The flexible master of claim 7, wherein the rigid backing is at least one of a block and a rigid plate.

9. The flexible master of claim 1, wherein the patterned surface is created by at least one of step-and-repeat indenting and ultrasonic nanocoining.

10. The flexible master of claim 1, wherein the foil or film is a seamless sleeve.

11. The flexible master of claim 10, wherein the seamless sleeve is self-supporting.

12. The flexible master of claim 1, wherein the foil or film have a thickness from about 0.001 inches to about 0.02 inches.

13. A semi-transparent photomask comprising:
a transparent substrate; and
an opaque material deposited on the transparent substrate, wherein the opaque material comprises a pattern of micro- or nanopatterned features configured to impart the pattern to an unpatterned surface, wherein the micro- or nanopatterned features are generated by an indenting process.

14. The semi-transparent photomask of claim 13, wherein the transparent substrate is at least one of a glass, quartz, fused silica, and polymer.

15. The semi-transparent photomask of claim 13, wherein the opaque material is at least one of a metal, a ceramic, or a polymer.

16. The semi-transparent photomask of claim 13, wherein the pattern is created by at least one of step-and-repeat indenting and ultrasonic nanocoining.

17. The semi-transparent photomask of claim 13, wherein the thickness of the opaque material varies across at least one of the length or the width of the transparent substrate.

18. A semi-transparent photomask comprising:
a transparent substrate comprising a pattern of micro- or nanopatterned features configured to impart the pattern to an unpatterned surface; and
an opaque material deposited on the transparent substrate and filling the micro- or nanopatterned features of the transparent substrate,
wherein the micro- or nanopatterned features are generated through an indenting process.

19. The semi-transparent photomask of claim 18, wherein the pattern is created by at least one of an indenting process and an imprinting process.

20. A method of fabricating a conformal master and/or semi-transparent photomask, the method comprising:
providing a foil or film over a base cylinder, the foil or film formed as a seamless sleeve or a sheet of material;
indenting the foil or film with a pattern of micro- or nanopatterned features;
cutting the indented foil or film; and
flattening the cut and indented foil or film.

21. The method of claim 20, wherein the foil or film is diamond turned to an optical finish prior to indenting.

22. The method of claim 20, wherein the indenting is carried out using a die.

23. The method of claim 22, wherein the die is patterned with the micro- or nanopatterned features by at least one of a focused ion beam and masking and etching.

24. The method of claim 20, wherein the die is a diamond die.

25. The method of claim 20, wherein the indenting is carried out using a piezo-driven actuator.
